(19) United States
(12) Patent Application Publication
(10) Pub. No.: US 2025/0207021 A1
(43) Pub. Date: Jun. 26, 2025

(54) QUANTUM DOT AND PREPARATION METHOD THEREOF, AND LIGHT-EMITTING DEVICE

(71) Applicants: Guangdong Juhua Research Institute of Advanced Display, Guangzhou (CN); TCL Technology Group Corporation, Huizhou (CN)

(72) Inventors: Likuan ZHOU, Guangzhou (CN); Wenjun HOU, Guangzhou (CN)

(73) Assignees: Guangdong Juhua Research Institute of Advanced Display, Guangzhou (CN); TCL Technology Group Corporation, Huizhou (CN)

(21) Appl. No.: 18/988,471

(22) Filed: Dec. 19, 2024

(30) Foreign Application Priority Data
Dec. 20, 2023 (CN) 202311767375.6

(51) Int. Cl. C09K 11/56; B82Y 20/00; B82Y 40/00; C09K 11/88; H10K 50/115; H10K 85/10

(52) U.S. Cl. CPC C09K 11/565; C09K 11/883; H10K 85/1135; H10K 85/115; H10K 85/151; B82Y 20/00; B82Y 40/00; H10K 50/115

(57) ABSTRACT

The present disclosure provides a quantum dot and preparation method thereof, and light-emitting device. The method of preparing the quantum dot comprising: providing a single molecule source precursor solution, the single molecule source precursor solution comprises a single molecule source precursor compound comprising a first metal ion and a first anion; heating the single molecule source precursor solution to obtain a sulfur-containing quantum core; and forming one or more shell layers on the surface of the sulfur-containing quantum dot core to obtain the quantum dot. The sulfur-containing quantum dot core prepared by the method have few defects, thereby the defects of the generated quantum dot are reduced.

This application claims priority to Chinese Application No. 202311767375.6, entitled “QUANTUM DOT AND PREPARATION METHOD THEREOF, AND LIGHT-EMITTING DEVICE”, filed on Dec. 20, 2023. The entire disclosures of the above application are incorporated herein by reference.

### TECHNICAL FIELD

The present disclosure relates to a field of display technologies, and more particularly, to a quantum dot and preparation method thereof, and a light-emitting device.

### BACKGROUND

In display technology, the lifetime of the quantum dot is determined by the internal structure of quantum dot. There are defects inside the quantum dot, which will affect the lifetime of excitons and the efficiency of radiation transition, resulting in the phenomenon of excitons being quenched.

Quantum dot include core-shell quantum dot. The quantum dot core of the core-shell quantum dot usually adopts the hot injection method, which is to inject anionic precursor liquid into a high-temperature cationic precursor solution. Due to the short contact time between the anionic precursor and the cationic precursor, a large number of defects exist in the quantum dot core, and then the defects of the obtained quantum dot increase.

### TECHNICAL SOLUTION

In view of this, the present disclosure provides a quantum dot and preparation method thereof, and a light-emitting device, and aims to solve the problem that conventional quantum dot has lots of defects.

Embodiments of the present disclosure is realized as follows: a method of preparing a quantum dot including:
providing a single molecule source precursor solution, the single molecule source precursor solution includes a single molecule source precursor compound comprising a first metal ion and a first anion;
heating the single molecule source precursor solution to obtain a sulfur-containing quantum core;
forming one or more shell layers on the surface of the sulfur-containing quantum dot core to obtain the quantum dot;
wherein the first anion is selected from one or more of Formula (I), Formula (II), and Formula (III), and the structures of Formula (I), Formula (II), and Formula (III) are as follows:

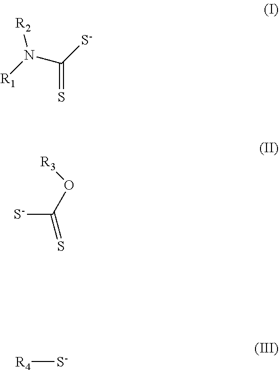

where R₁, R₂, R₃, and R₄ are independently selected from one of a substituted or unsubstituted C₁-C₂₄ alkyl group, a substituted or unsubstituted C₃-C₁₀ cycloalkyl group, a substituted or unsubstituted aryl group having 6 to 24 ring atoms, and a substituted or unsubstituted heteroaryl group having 5 to 24 ring atoms;
the substituted substituent is selected from deuterium, amino, halogen, hydroxyl, carboxyl, nitro, aldehyde, cyano, C₁-C₆ alkyl, C₁-C₆ alkoxy, C₁-C₆ alkoxycarbonyl, and C₁-C₆ alkylacyloxy.

In some embodiments, R₁, R₂, R₃, and R₄ are independently selected from C₁-C₁₆ alkyl group.

In some embodiments, the first metal ion is selected from one or more of zinc ion, cadmium ion, indium ion, lead ion, and mercury ion.

In some embodiments, the first anion includes one or more of dithiocarbamate acid radical, xanthate acid radical, and thiol anion.

In some embodiments, the dithiocarbamate acid radical includes one or more of dimethyldithiocarbamate acid radical, diethyldithiocarbamate acid radical, dipropyldithiocarbamate acid radical, and dibutyldithiocarbamate acid radical.

In some embodiments, the xanthate acid radical includes one or more of methyl xanthate acid radical, ethyl xanthate acid radical, propyl xanthate acid radical, butyl xanthate acid radical, tetradecyl xanthate acid radical, pentadecyl xanthate acid radical, and hexadecyl xanthate acid radical.

In some embodiments, the thiol anion is selected from one or more of methanethiol anion, ethanethiol anion, propanethiol anion, and dodecanethiol anion.

In some embodiments, the single molecule source precursor solution further includes a second metal ion and/or a second anion source.

In some embodiments, the second metal ion is selected from one or more of zinc ion, cadmium ion, indium ion, lead ion, and mercury ion.

In some embodiments, the second anion source includes one or more of selenium source, phosphorus source, and antimony source; wherein the selenium source includes one or more of elemental selenium, sodium selenide, and potassium selenide; the phosphorus source includes one or more of elemental phosphorus, trialkylphosphine, tris (trialkylsilyl) phosphine, tris (dialkylsilyl) phosphine, and tris (dialkylamino) phosphine; and the antimony source includes one or more of elemental antimony, antimony tribromide, and antimony chloride.

In some embodiments, a solvent of the single molecule source precursor solution includes a coordinating solvent and/or a non-coordinating solvent.

In some embodiments, the coordinating solvent includes an aliphatic amine compound having 4 to 30 carbon atoms and/or an acid compound having 4 to 24 carbon atoms, the aliphatic amine compound includes an alkylamine and/or an alkenylamine, the acid compound includes a fatty acid compound, and the fatty acid compound includes an alkenoic acid.

In some embodiments, the coordinating solvent includes one or more of octylamine, dioctylamine, trioctylamine, oleylamine, oleic acid, linoleic acid, stearic acid, palmitic acid, dodecenoic acid, tridecenoic acid, tetradecenoic acid, pentadecenoic acid, hexadecenoic acid, and heptadecenoic acid.

In some embodiments, the non-coordinating solvent includes a hydrocarbon compound, and the hydrocarbon compound includes an alkene having 6 to 24 carbon atoms and/or an alkane having 6 to 24 carbon atoms.

In some embodiments, the non-coordinating solvent includes one or more of dodecene, tetradecene, hexadecene, heptadecene, octadecene, and paraffin.

In some embodiments, the heating includes:
heating at a first temperature for a first preset time to obtain a sulfur-containing quantum dot;
wherein the first temperature is 200-280° C., and the first preset time is 20-120 min.

In some embodiments, before the heating, the method further includes preheating, and the preheating includes:
heating at a second temperature for a second preset time;
wherein the second temperature is 80-200° C., and the second preset time is 20-120 min.

In some embodiments, before the preheating, the method further includes pretreatment, and the pretreatment includes:
heating at a third temperature for a third preset time;
wherein, the third temperature is 25-60° C., and the third preset time is 20-120 min.

Accordingly, the present disclosure further provides a quantum dot prepared by the method above.

In some embodiments, a material of the sulfur-containing quantum dot core is selected from one or more of ZnS, CdS, InS, PbS, HgS, ZnCdS, ZnInS, ZnPbS, ZnHgS, CdInS, CdPbS, CdHgS, InPbS, InHgS, PbHgS, ZnSeS, CdSeS, InSeS, PbSeS, HgSeS, ZnPS, CdPS, InPS, PbPS, HgPS, ZnSbS, CdSbS, InSbS, PbSbS, HgSbS, ZnCdSeS, ZnInSeS, ZnPbSeS, ZnHgSeS, CdInSeS, CdPbSeS, CdHgSeS, InPbSeS, InHgSeS, PbHgSeS, ZnCdPS, ZnInPS, ZnPbPS, ZnHgPS, CdInPS, CdPbPS, CdHgPS, InPbPS, InHgPS, PbHgPS, ZnCdSbS, ZnInSbS, ZnPbSbS, ZnHgSbS, CdInSbS, CdPbSbS, CdHgSbS, InPbSbS, InHgSbS, PbHgSbS.

In some embodiments, materials of each of the shell layers are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, CuInS₂, CuInSe₂, and AgInS₂.

Accordingly, the present disclosure further provides a light-emitting device comprising an anode, a light-emitting layer, and a cathode which are stacked, wherein the light-emitting layer includes the quantum dot above.

In the present disclosure, the sulfur-containing quantum dot core is prepared by the single molecule source precursor solution. Since the single molecule source precursor solution includes the first metal ion and the first anion, the first metal ion and the first anion can react slowly, thereby reducing the defects of the sulfur-containing quantum dot core, and finally reducing the defects of the generated quantum dots.

### BRIEF DESCRIPTION OF DRAWINGS

In order to more clearly explain the technical solutions in the embodiments of the present disclosure, the drawings to be used in the description of the embodiments are briefly described below. It is apparent that the drawings in the following description are merely some embodiments of the present disclosure. For those skilled in the art, without involving any creative effort, other drawings may be obtained based on these drawings.

FIG. 1 is a flowchart of a method of preparing a quantum dot according to an embodiment of the present disclosure.

FIG. 2 is a flowchart of a method of preparing a single molecule source precursor compound according to an embodiment of the present disclosure.

FIG. 3 is a schematic diagram of an upright light-emitting device according to an embodiment of the present disclosure;

FIG. 4 is a schematic diagram of an inverted light-emitting device according to an embodiment of the present disclosure;

FIG. 5 is a transmission electron microscope image of the sulphur-containing quantum dot cores of Example 2 according to an embodiment of the present disclosure;

FIG. 6 is a transmission electron microscope image of the sulphur-containing quantum dot cores of Example 5 according to an embodiment of the present disclosure;

FIG. 7 is a transmission electron microscope image of the sulphur-containing quantum dot cores of Comparative Example 1 according to an embodiment of the present disclosure;

FIG. 8 is a transmission electron microscope image of the sulphur-containing quantum dot core of Comparative Example 2 according to an embodiment of the present disclosure.

### DESCRIPTION OF REFERENCE NUMBERS

100, light-emitting device; 10, anode; 20, light-emitting layer; 30, cathode; 40, hole functional layer; 50, electron functional layer.

### DETAILED DESCRIPTION

Technical solutions in embodiments of the present disclosure will be clearly and completely described below with reference to the drawings in the embodiments of the present disclosure. It is apparent that, the described embodiments are only a part of embodiments of the present disclosure, rather than all the embodiments. Based on the embodiments in the present disclosure, all other embodiments obtained by those skilled in the art without creative effort fall within the protection scope of the present disclosure. Furthermore, it should be understood that the detailed description described herein is for illustration and explanation of the present disclosure only, and is not intended to limit the present disclosure.

In the present disclosure, unless stated to the contrary, the location words used such as “upper” and “lower” usually refer to the upper and lower in the actual use or working state of the device, specifically the drawing direction in the accompanying drawings; while “inner” and “outer” are for the outline of the device. In addition, in the description of the present disclosure, the term “comprising/including” means “comprising/including but not limited to”. The terms first, second, third, etc. are used for indication only, and do not impose numerical requirements or establish order.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, and the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural (multiple).

Various embodiments of the present disclosure may be presented in a form of range. It should be understood that the description in the form of range is merely for convenience and brevity, and should not be construed as a hard limitation on the scope of the disclosure. Therefore, it should be considered that the recited range description has specifically disclosed all possible subranges, as well as a single numerical value within that range. For example, it should be considered that a description of a range from 1 to 6, more specifically, a range such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

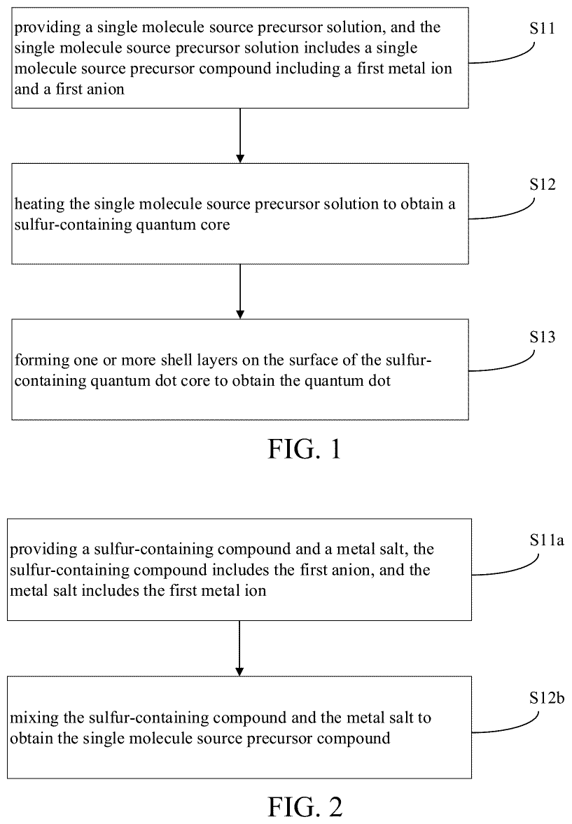

Referring to FIG. 1, the present disclosure provides a method of preparing a quantum dot including:

Step S11: providing a single molecule source precursor solution, and the single molecule source precursor solution includes a single molecule source precursor compound including a first metal ion and a first anion;

Step S12: heating the single molecule source precursor solution to obtain a sulfur-containing quantum core;

Step S13: forming one or more shell layers on the surface of the sulfur-containing quantum dot core to obtain the quantum dot.

In the Step S11:

The first anion is selected from one or more of Formula (I), Formula (II), and Formula (III). The structures of Formula (I), Formula (II), and Formula (III) are as follows:

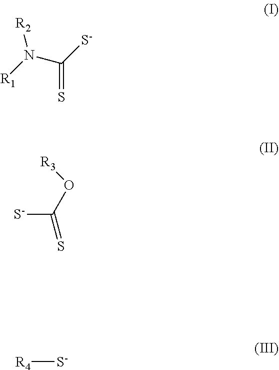

Where R₁, R₂, R₃, and R₄ are independently selected from one of a substituted or unsubstituted C₁-C₂₄ alkyl group, a substituted or unsubstituted C₃-C₁₀ cycloalkyl group, a substituted or unsubstituted aryl group having 6 to 24 ring atoms, and a substituted or unsubstituted heteroaryl group having 5 to 24 ring atoms.

The substituted substituent is selected from deuterium, amino, halogen, hydroxyl, carboxyl, nitro, aldehyde, cyano, C₁-C₆ alkyl, C₁-C₆ alkoxy, C₁-C₆ alkoxycarbonyl, and C₁-C₆ alkylacyloxy.

Preferably, R₁, R₂, R₃, R₄ are independently selected from unsubstituted C₁ alkyl, unsubstituted C₂ alkyl, unsubstituted C₃ alkyl, unsubstituted C₄ alkyl, unsubstituted C₅ alkyl, unsubstituted C₆ alkyl, unsubstituted C₇ alkyl, unsubstituted C₈ alkyl, unsubstituted C₉ alkyl, unsubstituted C₁₀ alkyl, unsubstituted C₁₂ alkyl, unsubstituted C₁₄ alkyl, and unsubstituted C₁₆ alkyl.

In some embodiments, the first metal ion is selected from one or more of zinc ion, cadmium ion, indium ion, lead ion, and mercury ion.

In some embodiments, the first anion includes one or more of dithiocarbamate acid radical, xanthate acid radical, and thiol anion. The dithiocarbamate acid radical includes one or more of dimethyldithiocarbamate acid radical, diethyldithiocarbamate acid radical (DDTC), dipropyldithiocarbamate acid radical, and dibutyldithiocarbamate acid radical. The xanthate acid radical includes one or more of methyl xanthate acid radical, ethyl xanthate (ex) acid radical, propyl xanthate acid radical, butyl xanthate acid radical, tetradecyl xanthate acid radical, pentadecyl xanthate acid radical, and hexadecyl xanthate acid radical. The thiol anion is selected from one or more of methanethiol anion (CH₃S⁻), ethanethiol anion (C₂H₅S⁻), propanethiol anion (C₃H₇S⁻), and dodecanethiol anion (C₁₂H₂₅S⁻).

Specifically, the single molecule source precursor solution of the present disclosure includes a first metal ion and a first anion. The first metal ion and the first anion can react slowly, thereby reducing defects of the sulfur-containing quantum dot core, and ultimately reducing defects of the quantum dot. A molar ratio of the elements in the sulfur-containing quantum dot core is consistent with that in the single molecule source precursor solution.

In some embodiments, the single molecule source precursor solution further includes a second metal ion and/or a second anion source. The first metal ion and the second metal ion are each independently selected from one or more of zinc ion, cadmium ion, indium ion, lead ion, and mercury ion. The second anion source includes one or more of selenium source, phosphorus source, and antimony source. Optionally, the selenium source includes one or more of elemental selenium, sodium selenide, and potassium selenide. Optionally, the phosphorus source includes one or more of elemental phosphorus, trialkylphosphine, tris (trialkylsilyl) phosphine, tris (dialkylsilyl) phosphine, and tris (dialkylamino) phosphine. Optionally, the antimony source includes one or more of elemental antimony, antimony tribromide, and antimony chloride. It should be noted that the second metal ion source and/or the second anion source are provided in addition to the first metal ion. The trialkylphosphine may include triethylphosphine, tributylphosphine, tripropylphosphine, and the like.

In some embodiments, a solvent of the second anion source includes one or more of trioctyl phosphate (TOP), tributyl phosphate (TBP), n-octadecane (ODE), oleylamine (OLAM), and tetramethylsilane (TMS).

In some embodiments, the second anion source may further include a third anion. The third anion includes one or more of acetate ion, nitrate ion, halogen ion, phosphate ion, and carbonate ion. The halogen ion includes one or more of fluoride ion, chloride ion, bromide ion, and iodide ion.

In some embodiments, by providing the second anion source on the basis of the first metal ion and the first anion, the types of elements can be increased, the single molecule source precursor solution containing more element types can be obtained, and then sulfur-containing quantum dot core containing more element types can be obtained, and finally the quantum dot containing more element types can be obtained.

In some embodiments, the first metal ion and the second metal ion may be the same or different. If the first metal ion and the second metal ion are the same, the proportion of the single molecule source precursor solution can be adjusted to obtain different proportions of sulfur-containing quantum dot cores, and finally different proportions of quantum dots can be obtained. If the first metal ion and the second metal ion are different, the element types of the single molecule source precursor solution can be adjusted to obtain sulfur-containing quantum dot core containing different element types, and finally obtain quantum dots containing different element types.

In some embodiments, a solvent of the single molecule source precursor solution includes a coordinating solvent and/or a non-coordinating solvent.

The coordinating solvent includes an aliphatic amine compound having 4 to 30 carbon atoms and/or an acid compound having 4 to 24 carbon atoms in the main chain. For example, the aliphatic amine compound having 9, 12, 15, 18, 21, or 24 carbon atoms, and the fatty acid compounds having 6, 12, 13, 14, 15, 16, 18, 20, or 22 carbon atoms in the main chain.

Moreover, the aliphatic amine compound includes an alkylamine and/or an alkenylamine. The acid compound includes a fatty acid compound. The fatty acid compound includes an alkenoic acid. The coordinating solvent includes one or more of octylamine, dioctylamine, trioctylamine, oleylamine (also known as OLAM), oleic acid, linoleic acid, stearic acid, palmitic acid, dodecenoic acid, tridecenoic acid, tetradecenoic acid, pentadecenoic acid, hexadecenoic acid, and heptadecenoic acid.

The non-coordinating solvent includes a hydrocarbon compound.

Moreover, the hydrocarbon compound includes an alkene having 6 to 24 carbon atoms in the main chain and/or an alkane having 6 to 24 carbon atoms in the main chain. For example, the alkene having 6, 8, 10, 12, 15, 18, 21, or 24 carbon atoms, and the alkane having 6, 8, 10, 12, 13, 14, 15, or 16 carbon atoms in the main chain. The non-coordinating solvent includes one or more of dodecene, tetradecene, hexadecene, heptadecene, octadecene (ODE), and paraffin.

In some embodiments, when the coordinating solvent and the non-coordinating solvent are used simultaneously, a volume ratio of the coordinating solvent and the non-coordinating solvent is 1:(1-5). For example, the volume ratio of the coordinating solvent and the non-coordinating solvent is 1:1, 1:2, 1:3, 1:4, or 1:5.

In some embodiments, before heating the single molecule source precursor solution further includes a step of removing water and oxygen. A method of removing water and oxygen includes:

removing water and oxygen of the coordinating solvent and/or the non-coordinating solvent at a fourth temperature; then reducing to a fifth temperature; adding the single molecule source precursor solution; and removing water and oxygen water and oxygen at a sixth temperature.

The fourth temperature is 100-150° C., and the duration of the fourth temperature is 20-120 min. For example, the fourth temperature may be 110° C., 123° C., 128° C., 136° C., or 142° C.; the duration of the fourth temperature may be 21 min, 25 min, 30 min, 37 min, or 39 min. The step of removing water and oxygen of the coordinating solvent and/or the non-coordinating solvent at a fourth temperature can remove water, oxygen, and/or impurities in the coordinating solvent and the non-coordinating solvent.

The fifth temperature is 25-60° C., and the duration of the fifth temperature is 20-120 min. For example, the fifth temperature may be 26° C., 30° C., 36° C., 4° C., or 55° C.; the duration of the fifth temperature may be 40 min, 60 min, 80 min, 100 min, or 110 min. At the temperature of the fifth temperature, it is possible to ensure that the single molecule source precursor solution does not react.

The sixth temperature is 25-60° C., and the duration of the sixth temperature is 20-120 minutes. For example, the sixth temperature is 26° C., 30° C., 36° C., 42° C., or 55° C. The duration of the sixth temperature is 40 min, 60 min, 80 min, 100 min, or 110 min. At the temperature of the sixth temperature, water and oxygen can be removed.

In some embodiments, referring to FIG. 2, the method of preparing a quantum dot further includes: preparing the single molecule source precursor compound. A method of preparing the single molecule source precursor compound includes:

Step S11a: providing a sulfur-containing compound and a metal salt, the sulfur-containing compound includes the first anion, and the metal salt includes the first metal ion;

Step S12b, mixing the sulfur-containing compound and the metal salt to obtain the single molecule source precursor compound.

In the Step S11a:
The first anion is selected from one or more of Formula (I), Formula (II), and Formula (III). The structures of Formula (I), Formula (II), and Formula (III) are as follows:

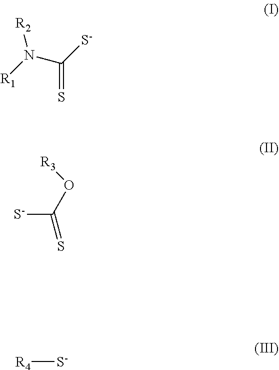

Where R₁, R₂, R₃, and R₄ are independently selected from one of a substituted or unsubstituted C₁-C₂₄ alkyl group, a substituted or unsubstituted C₃-C₁₀ cycloalkyl group, a substituted or unsubstituted aryl group having 6 to 24 ring atoms, and a substituted or unsubstituted heteroaryl group having 5 to 24 ring atoms.

The substituted substituent is selected from deuterium, amino, halogen, hydroxyl, carboxyl, nitro, aldehyde, cyano, C₁-C₆ alkyl, C₁-C₆ alkoxy, C₁-C₆ alkoxycarbonyl, and C₁-C₆ alkylacyloxy.

Preferably, R₁, R₂, R₃, R₄ are independently selected from unsubstituted C₁ alkyl, unsubstituted C₂ alkyl, unsubstituted C₃ alkyl, unsubstituted C₄ alkyl, unsubstituted C₅ alkyl, unsubstituted C₆ alkyl, unsubstituted C₇ alkyl, unsubstituted C₈ alkyl, unsubstituted C₉ alkyl, unsubstituted C₁₀ alkyl, unsubstituted C₁₂ alkyl, unsubstituted C₁₄ alkyl, and unsubstituted C₁₆ alkyl.

In some embodiments, the first anion includes one or more of dithiocarbamate acid radical, xanthate acid radical, and thiol anion. The dithiocarbamate acid radical includes one or more of dimethyldithiocarbamate acid radical, diethyldithiocarbamate acid radical (DDTC), dipropyldithiocarbamate acid radical, and dibutyldithiocarbamate acid radical. The xanthate acid radical includes one or more of methyl xanthate acid radical, ethyl xanthate (ex) acid radical, propyl xanthate acid radical, butyl xanthate acid radical, tetradecyl xanthate acid radical, pentadecyl xanthate acid radical, and hexadecyl xanthate acid radical. The thiol anion is selected from one or more of methanethiol anion (CH₃S⁻), ethanethiol anion (C₂H₅S⁻), propanethiol anion (C₃H₇S⁻), and dodecanethiol anion (C₁₂H₂₅S⁻).

In some embodiments, the sulfur-containing compound includes a cation. The cation includes one or more of potassium ion, sodium ion, and lithium ion.

In some embodiments, the metal salt includes one or more of acetate salt, nitrate salt, halide salt, phosphate salt, and carbonate salt. The halogen salt includes one or more of a fluoride salt, a chloride salt, a bromide salt, and an iodide salt.

In some embodiments, the first metal ion is selected from one or more of zinc ion, cadmium ion, indium ion, lead ion, and mercury ion.

In some embodiments, the step of mixing the sulfur-containing compound and the metal salt includes: mixing a sulfur-containing compound solution and a metal salt solution, wherein the sulfur-containing compound solution includes the sulfur-containing compound, and the metal salt solution includes the metal salt. In some embodiments, a concentration of the sulfur-containing compound solution is 0.2-10 mmol/mL. A concentration of the metal salt solution is 0.1-20 mmol/mL. For example, the concentration of the sulfur-containing compound solution may be 0.7 mmol/mL, 3 mmol/mL, 5 mmol/mL, 7 mmol/mL, or 9 mmol/ml. The concentration of the of the metal salt solution may be 5 mmol/mL, 8 mmol/mL, 10 mmol/mL, 12 mmol/mL, 16 mmol/mL, or 19 mmol/mL.

Moreover, a molar ratio of the sulfur-containing compound to the metal salt is (1-2):1, for example, 1.2:1, 1.4:1, 16:1, 18:1, or 1.9:1.

In the step S11b:

In some embodiments, a method of the mixing may be stirring. A time of the mixing may be 0.5-10 h. For example, the time of the mixing may be 3 h, 5 h, 7 h, 8 h, or 9 h.

In some embodiments, the method of preparing the single molecule source precursor compound further includes: washing and drying the single molecule source precursor compound.

Alternatively, the washing includes: washing precipitate with deionized water.

Alternatively, the drying may be vacuum drying at room temperature. A time of the drying may be 20-24 h. For example, the time of the drying may be 21 h, 22 h, 22.5 h, 23 h, or 23.5 h.

In the step S12:

The step of heating includes: heating at a first temperature for a first preset time to obtain a sulfur-containing quantum dot.

Moreover, the first temperature is 200-280° C., and the first preset time is 20-120 min. For example, the first temperature may be 210° C., 230° C., 240° C., 250° C., or 260° C. The first preset time may be 20 min, 40 min, 60 min, 80 min, 120 min, or 140 min.

In the present disclosure, the first metal ion, the second metal ion, the second anion source and the first anion can be cured by reacting at 200-280° C. for 20-120 min, and the morphology and quality of the crystal can be controlled. At the same time, at the first temperature and the first preset time, the first metal ion, the second metal ion, the second anion source, and the first anion can be further slowly released.

In some embodiments, before the step of heating, the method of preparing a quantum dot further includes: preheating. The preheating includes: heating at a second temperature for a second preset time.

Moreover, the second temperature is 80-200° C., and the second preset time is 20-120 min. For example, the second temperature may be 85° C., 100° C., 120° C., 140° C., or 160° C. The second preset time may be 40 min, 60 min, 80 min, 100 min, or 110 min. The preheating facilitates the slow release of the first metal ion, the second metal ion, the second anion source, and the first anion.

In some embodiments, slowly releasing the first metal ion, the second metal ion, the second anion source, and the first anion at 80-200° C. can effectively reduce lattice defects, and can further ensure regular morphology, which provides a guarantee for obtaining quantum dot with high fluorescence quantum yield. At the same time, it can also ensure that the element ratio of the sulfur-containing quantum dot is consistent with preset ratio of the first metal ion, the second metal ion, the second anion source and the first anion.

Specifically, slowly releasing the first metal ion, the second metal ion, the second anion source and the first anion at 80-200° C. can avoid rapid temperature changes in the growth process of the crystal, thereby reducing defects such as cracks and dislocations in the crystal. At the same time, slowly releasing the first metal ion, the second metal ion, the second anion source and the first anion at 80-200° C. can also promote the improvement of the crystallinity and the order degree of the crystal, and making the internal structure of the crystal more stable and the morphology more regular, so that the quantum dot has better fluorescence performance. In addition, slowly releasing the first metal ion, the second metal ion, the second anion source and the first anion at 80-200° C. can also ensure that the element molar ratio of the sulfur-containing quantum dot core is consistent with the preset element molar ratio of the first metal ion, the second metal ion, the second anion source and the first anion. The consistency can ensure that sulfur-containing quantum dot core has higher chemical stability and optical properties, thereby providing a better guarantee for practical applications.

In some embodiments, before the step of preheating, the method of preparing a quantum dot further includes: pretreatment. The pretreatment includes: heating at a third temperature for a third preset time.

Moreover, the third temperature is 25-60° C., and the third preset time is 20-120 min. For example, the third temperature may be 26° C., 30° C., 36° C., 42° C., or 55° C. The third preset time may be 40 min, 60 min, 80 min, 100 min, or 110 min. The pretreatment is used for removing water and oxygen.

In the step S13:

In some embodiments, a number of shell layers is 1-5 layers. For example, the number of shell layers may be 1 layer, 2 layers, 3 layers, 4 layers, or 5 layers.

In some embodiments, materials of each of the shell layers are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, CuInS₂, CuInSe₂, and AgInS₂.

Embodiments of the present disclosure further provides a quantum dot, wherein the quantum dot is prepared by the above-described method of preparing a quantum dot. The quantum dot includes a sulfur-containing quantum dot core and at least one shell layer coated on an outer surface of the sulfur-containing quantum dot core.

In some embodiments, a material of the sulfur-containing quantum dot core is selected from one or more of ZnS, CdS, InS, PbS, HgS, ZnCdS, ZnInS, ZnPbS, ZnHgS, CdInS, CdPbS, CdHgS, InPbS, InHgS, PbHgS, ZnSeS, CdSeS, InSeS, PbSeS, HgSeS, ZnPS, CdPS, InPS, PbPS, HgPS, ZnSbS, CdSbS, InSbS, PbSbS, HgSbS, ZnCdSeS, ZnInSeS, ZnPbSeS, ZnHgSeS, CdInSeS, CdPbSeS, CdHgSeS, InPbSeS, InHgSeS, PbHgSeS, ZnCdPS, ZnInPS, ZnPbPS, ZnHgPS, CdInPS, CdPbPS, CdHgPS, InPbPS, InHgPS, PbHgPS, ZnCdSbS, ZnInSbS, ZnPbSbS, ZnHgSbS, CdInSbS, CdPbSbS, CdHgSbS, InPbSbS, InHgSbS, PbHgSbS.

In some embodiments, the sulfur-containing quantum dot core may act as a luminescent core. For example, the luminescent core emits red light or blue light. Moreover, a wavelength range of red light is 620-640 nm, and a wavelength range of blue light is 460-480 nm. For example, the wavelength range of red light may be 625 nm, 627 nm, 630 nm, 635 nm, or 637 nm. The wavelength range of blue light may be 465 nm, 467 nm, 470 nm, 475 nm, or 477 nm.

In some embodiments, materials of each of the shell layers are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, CuInS₂, CuInSe₂, and AgInS₂.

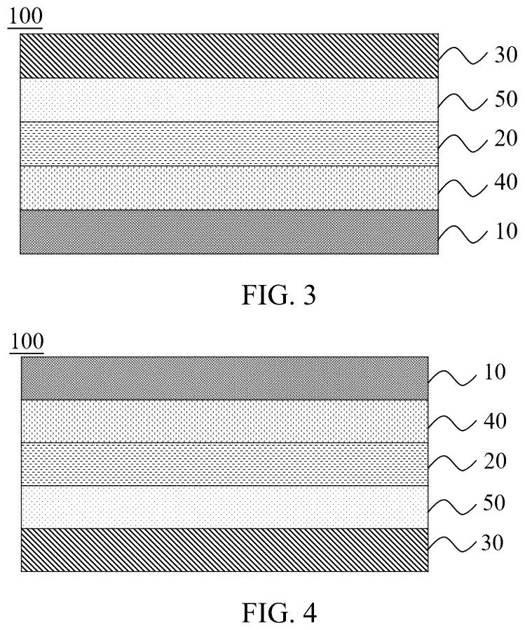

Referring to FIG. 3 and FIG. 4, the present disclosure provides a light-emitting device 100. The light-emitting device 100 includes an anode 10, a light-emitting layer 20, and a cathode 30 which are stacked. The light-emitting layer 20 includes the above-described quantum dot.

Materials of the anode 10 and the cathode 30 are each independently selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, aluminum-doped magnesium oxide, AZO/Ag/AZO, AZO/Al/AZO, ITO/Ag/ITO, ITO/Ag/ITO, ZnO/Ag/ZnO, ZnS/Ag/ZnS, Ag, Al, Cu, Mo, Au, Pt, Si, Ca, Mg, and Ba.

The light-emitting device 100 further includes a hole functional layer 40 including a hole transport layer and/or a hole injection layer. When the hole functional layer 40 includes the hole transport layer and the hole injection layer, the hole injection layer is disposed between the light-emitting layer 20 and the anode 10, and the hole transport layer is disposed between the light-emitting layer 20 and the hole injection layer.

A material of the hole transport layer may be a material known in the art for use in the hole transport layer, for example, may include but not limited to one or more of 4,4′-N,N′-dicarbcarbazolyl-biphenyl (CBP), poly [bis(4-phenyl) (2,4,6-trimethylphenyl) amine](PTAA), N,N′-diphenyl-N,N′-bis (1-naphthyl)-1,1′-biphenyl-4,4″-diamine (α-NPD), N,N′-diphenyl-N,N′-bis (1-naphthyl)-4,4′-diamine (TPD), poly (N,N′bis(4-butylphenyl)-N,N′-bis (phenyl) benzidine) (Poly-TPD), N,N′-bis(3-methylphenyl)-N,N′-bis (phenyl)-spiro (spiro-TPD), N,N′-bis(4-(N,N′-diphenyl-amino) phenyl)-N,N′-diphenyl benzidine (DNTPD), 4,4′,4′-tris (N-carbazolyl)-triphenylamine (TCTA), 4,4′,4′-tris (N-3-methylphenyl-N-phenylamino) triphenylamine (m-MTDATA), poly [(9,9′-dioctyl fluorene-2,7-diyl)-co-(4,4′-(N-(4-sec-butylphenyl) diphenylamine))](TFB), poly (N-vinylcarbazole) (PVK) and its derivatives, N,N′-bis(1-naphthyl)-N,N′-diphenyl-1,1′-biphenyl-4-4′-diamine (NPB), spiro NPB, poly (phenylene vinylene) (PPV), poly [2-methoxy-5-(2-ethylhexyloxy)-1,4-phenylene vinylene](MEH-PPV), poly [2-methoxy-5-(3′,7′-dimethyloctyloxy)-1,4-phenylene vinylene](MOMO-PPV), 2,2′,7,7′-tetrakis [N,N-bis(4-methoxyphenyl) amino]-9,9′-spiro-fluorene (spiro-omeTAD), 4,4′-cyclohexyl bis [N,N-bis(4-methylphenyl) aniline](TAPC), 1,3-bis(carbazole-9-yl) benzene (MCP), polyaniline, polypyrrole, poly (p) phenylene vinylene, aromatic tertiary amine, polynuclear aromatic tertiary amine, 4,4′-bis (p-carbazolyl)-1,1′-biphenyl compound, N,N,N′,N′-tetraarylbenzidine, poly (3,4-ethylenedioxythiophene)-polystyrene sulfonic acid (PEDOT:PSS) and its derivatives, polymethacrylate and its derivatives, poly (9,9-octylfluorene) and its derivatives, polyspirofluorene and its derivatives, doped graphene, undoped graphene, C60, doped or undoped NiO, doped or undoped MoO₃, doped or undoped WO₃, doped or undoped V₂O₅, doped or undoped P-type gallium nitride, doped or undoped CrO₃, and doped or undoped CuO.

A material of the hole injection layer may be a material known in the art for use in the hole injection layer, for example, may include but not limited to one or more of 2,3,6,7,10,11-hexacyano-1,4,5,8,9,12-hexazaphenanthrene (HAT-CN), polyoxyethyl cephene (PEDOT), PEDOT:PSS, PEDOT:PSS doped with MoO₃ (PEDOT:PSS-MoO₃), 4,4′,4′-tris (N-3-methylphenyl-N-phenylamino) triphenylamine (m-MTDATA), tetracyanoquinone dimethane (F4-TCNQ), copper phthalocyanine, nickel oxide, molybdenum oxide, tungsten oxide, vanadium oxide, molybdenum sulfide, tungsten sulfide and copper oxide.

The light-emitting device 100 further includes an electron functional layer 50 disposed between the light-emitting layer 20 and the cathode 30. The electron functional layer 50 includes one or more of an electron injection layer and an electron transport layer.

A material of the electron transport layer is a material known in the art for the electron transport layer, for example, may be selected from but not limited to one or more of an inorganic electron transport material and an organic electron transport material. The inorganic electron transport material may include but not limited to one or more of a doped metal oxide particle, an undoped metal oxide particle, a ceramic semiconductor material, a Group IIB-VIA semiconductor material, a Group IIIA-VA semiconductor material, and a Group IB-IIIA-VIA semiconductor material. The metal oxide in the undoped metal oxide particle may include but not limited to one or more of ZnO, TiO₂, SnO₂, ZrO₂, Ta₂O₅. The metal oxide in the doped metal oxide may include but not limited to one or more of ZnO, TiO₂, SnO₂, ZrO₂, Ta₂O₅, and Al₂O₃, and the doping element in the doped metal oxide may include but not limited to one or more of Al, Mg, Li, Mn, Y, La, Cu, Ni, Zr, Ce, In, Ga, and Sn. For example, the doped metal oxide may be aluminum zinc oxide (AZO), lithium-doped zinc oxide (LZO), magnesium-doped zinc oxide (MZO), tin-doped zinc oxide (Sn—ZnO) and the like. The ceramic semiconductor material may include but not limited to barium titanate. The Group IIB-VIA semiconductor material may include but not limited to one or more of ZnS, ZnSe, and CdS. The Group IIIA-VA semiconductor material includes, but is not limited to, one or more of InP and GaP. The Group IB-IIIA-VIA semiconductor material may include but not limited to one or more of CuInS and CuGaS. The organic electron transport material may include one or more of a quinoxaline compound, an imidazole compound, a triazine compound, a fluorene-containing compound, and a hydroxyquinoline compound.

It can be understood that in addition to the above functional layers, the light-emitting device 100 may also include some functional layers conventionally used for light-emitting devices that contribute to improving the performance of the light-emitting devices, such as an electron blocking layer, a hole blocking layer, and/or an interface modification layer.

It can be understood that the material and thickness of each layer of the light-emitting device 100 can be set and adjusted accordingly according to the light-emitting requirements of the light-emitting device 100.

The light-emitting device 100 further includes a substrate (not shown in the drawings). The substrate may be a rigid substrate or a flexible substrate. The rigid substrate may be made of a ceramic material, various types of glass materials, and the like. The flexible substrate may be a substrate formed of a material such as a polyimide film (PI) and derivatives thereof, polyethylene naphthalate (PEN), phosphoenolpyruvate (PEP), diphenylene ether resin, and the like.

It can be understood that, referring to FIG. 3 and FIG. 4, the light-emitting device 100 may be an upright light-emitting device or an inverted light-emitting device. When the light-emitting device 100 is an upright light-emitting device, the substrate is bonded to the side of the anode 10 away from the light-emitting layer 20. When the light-emitting device 100 is an inverted light-emitting device, the substrate is bonded to a side of the cathode away from the light-emitting layer 20.

In some embodiments, a method of preparing the light-emitting layer 20 may employ conventional techniques in the art, such as a chemical method or a physical method. Among them, the chemical method may include chemical vapor deposition method, continuous ion layer adsorption and reaction method, anodic oxidation method, electrolytic deposition method and co-precipitation method. The physical method may include a physical coating method and a solution method. The physical coating method may include thermal evaporation coating method, electron beam evaporation coating method, magnetron sputtering method, multi-arc ion coating method, physical vapor deposition method, atomic layer deposition method, pulsed laser deposition method, and the like. The solution method may be spin coating method, printing method, ink jet printing method, blade coating method, printing method, dipping and pulling method, soaking method, spray coating method, roll coating method, casting method, slit coating method, strip coating method, and the like.

In some embodiments, a thickness of the anode 10 is 80-120 nm.

In some embodiments, a thickness of the cathode 30 may be 50-150 nm.

In some embodiments, a thickness of the light-emitting layer 20 may be 10-100 nm, for example, 15 nm, 40 nm, 50 nm, 60 nm, 80 nm, or 90 nm.

In some embodiments, a thickness of the electronically functional layer 50 may be 15-40 nm.

In some embodiments, a thickness of the hole functional layer 40 may be 20-90 nm. A thickness of the hole injection layer may be 10-40 nm, and a thickness of the hole transport layer may be 10-50 nm.

An embodiment of the present disclosure provides a display device. The display device may be any electronic product having a display function, and the electronic product may include but not limited to a smartphone, a tablet computer, a laptop computer, a digital camera, a digital video camera, a smart wearable device, a smart weighing electronic scale, a vehicle-mounted display, a television, or an electronic book reader. The smart wearable device may be, for example, a smart bracelet, a smart watch, a Virtual Reality (VR) helmet, and the like.

Hereinafter, the present disclosure will be specifically described with reference to specific examples, and the following examples are only partial examples of the present disclosure and do not limit the present disclosure.

### Example 1

This Example provides a quantum dot. The material of the quantum dot core is CdS, and the material of shell layer of the quantum dot is CdZnS/ZnS. The molar ratio of Cd:S of the quantum dot core is 1:4. A method of preparing the quantum dot is as follows:
20 mmol of sodium diethyldithiocarbamate (NaDDTC) was dissolved in 60 mL of aqueous solution under vigorous stirring, and 10 mmol of Cd(Ac)₂·2H₂O was dissolved in 100 mL of aqueous solution under vigorous stirring;
the aqueous solution of sodium diethyldithiocarbamate was dropwise added to the aqueous solution of Cd(Ac)₂·2H₂O, and mixed for 2 h to obtain white Cd(DDTC)₂;
the precipitate of Cd(DDTC)₂ was washed 3 times with deionized water and dried in a vacuum oven at room temperature for 24 h;
10 mL oleylamine (OLAM) and 20 mL octadecene (ODE) were added into a 100 mL three-neck flask, water and oxygen was removed at 100° C. for 30 minutes firstly, then the temperature was reduced to 25° C., 1 mmol Cd(DDTC)₂ was added, and the temperature was raised to 60° C. and continue for 30 minutes to remove water and oxygen to obtain a single molecule source precursor compound, and a molar ratio of Cd:S in the single molecule source precursor compound is 1:4;
the single molecule source precursor compound was continuously removed water and oxygen at 25° C. for 30 minutes, then the temperature was raised to 150° C. and react for 60 minutes, and then raised the temperature to 250° C. and reacted for 80 minutes to obtain sulfur-containing quantum dot core of CdS;
CdZnS/ZnS shells were epitaxial growth on the sulfur-containing quantum dot core of CdS.

### Example 2

This Example is basically the same as Example 1, except that the quantum dot core of this Example is CdZnS, and the molar ratio of Cd:Zn:S is 3:1:4.

20 mmol of sodium diethyldithiocarbamate (NaDDTC) was dissolved in 60 mL of aqueous solution under vigorous stirring, and 10 mmol of Zn(Ac)₂·2H₂O was dissolved in 100 mL of aqueous solution under vigorous stirring;
the aqueous solution of sodium diethyldithiocarbamate was dropwise added to the aqueous solution of Zn(Ac)₂·2H₂O, and mixed for 2 h to obtain white Zn(DDTC)₂;
the precipitate of Zn(DDTC)₂ was washed 3 times with deionized water and dried in a vacuum oven at room temperature for 24 h;
10 mL oleylamine (OLAM) and 20 mL octadecene (ODE) were added into a 100 mL three-neck flask, water and oxygen was removed at 100° C. for 30 minutes firstly, then the temperature was reduced to 25° C., 5 mmol Zn(DDTC)₂ and 15 mmol Cd(Ac)₂ were added, and the temperature was raised to 60° C. and continue for 30 minutes to remove water and oxygen to obtain a single molecule source precursor compound, and a molar ratio of Cd:Zn:S in the single molecule source precursor compound is 3:1:4;
the single molecule source precursor compound was continuously removed water and oxygen at 25° C. for 30 minutes, then the temperature was raised to 150° C. and react for 60 minutes, and then raised the temperature to 250° C. and reacted for 80 minutes to obtain sulfur-containing quantum dot core of CdZnS.

### Example 3

This Example is basically the same as Example 1, except that the quantum dot core of this Example is ZnSeS, and the molar ratio of Zn:Se:S is 5:3:20.

20 mmol of sodium diethyldithiocarbamate (NaDDTC) was dissolved in 60 mL of aqueous solution under vigorous stirring, and 10 mmol of Zn(Ac)₂·2H₂O was dissolved in 100 mL of aqueous solution under vigorous stirring;
the aqueous solution of sodium diethyldithiocarbamate was dropwise added to the aqueous solution of Zn(Ac)₂·2H₂O, and mixed for 2 h to obtain white Zn(DDTC)₂;
the precipitate of Zn(DDTC)₂ was washed 3 times with deionized water and dried in a vacuum oven at room temperature for 24 h;
10 mL oleylamine (OLAM) and 20 mL octadecene (ODE) were added into a 100 mL three-neck flask, water and oxygen was removed at 100° C. for 30 minutes firstly, then the temperature was reduced to 25° C., 5 mmol Zn(DDTC)₂ and 3 mmol Se/TOP were added, and the temperature was raised to 60° C. and continue for 30 minutes to remove water and oxygen to obtain a single molecule source precursor compound, and a molar ratio of Zn:Se:S in the single molecule source precursor compound is 5:3:20;
the single molecule source precursor compound was continuously removed water and oxygen at 25° C. for 30 minutes, then the temperature was raised to 150° C. and react for 60 minutes, and then raised the temperature to 250° C. and reacted for 80 minutes to obtain sulfur-containing quantum dot core of ZnSeS.

### Example 4

This Example is basically the same as Example 1, except that the quantum dot core of this Example is CdZnSeS, and the molar ratio of Cd:Zn:Se:S is 1:5:1:20.

20 mmol of sodium diethyldithiocarbamate (NaDDTC) was dissolved in 60 mL of aqueous solution under vigorous stirring, and 10 mmol of Zn(Ac)₂·2H₂O was dissolved in 100 mL of aqueous solution under vigorous stirring;
the aqueous solution of sodium diethyldithiocarbamate was dropwise added to the aqueous solution of Zn(Ac)₂·2H₂O, and mixed for 2 h to obtain white Zn(DDTC)₂;
the precipitate of Zn(DDTC)₂ was washed 3 times with deionized water and dried in a vacuum oven at room temperature for 24 h;
Cd(Ac)₂·2H₂O and Se/TOP were provided;
10 mL oleylamine (OLAM) and 20 mL octadecene (ODE) were added into a 100 mL three-neck flask, water and oxygen was removed at 100° C. for 30 minutes firstly, then the temperature was reduced to 25° C., 1 mmol Cd(AC)₂·2H₂O, 5 mmol Zn(DDTC)₂ and 1 mmol Se/TOP were added, and the temperature was raised to 60° C. and continue for 30 minutes to remove water and oxygen to obtain a single molecule source precursor compound, and a molar ratio of Cd:Zn:Se:S in the single molecule source precursor compound is 1:5:1:20;
the single molecule source precursor compound was continuously removed water and oxygen at 25° C. for 30 minutes, then the temperature was raised to 150° C. and react for 60 minutes, and then raised the temperature to 250° C. and reacted for 80 minutes to obtain sulfur-containing quantum dot core of CdZnSeS.

### Example 5

This Example is basically the same as Example 1, except that the quantum dot core of this Example is CdZnSeS, and the molar ratio of Cd:Zn:Se:S is 1:1:1:1.
the precipitate of Cd(DDTC)₂ was washed 3 times with deionized water and dried in a vacuum oven at room temperature for 24 h; and Zn(Ac)₂·2H₂O and Se/TOP were provided;
10 mL oleylamine (OLAM) and 20 mL octadecene (ODE) were added into a 100 mL three-neck flask, water and oxygen was removed at 100° C. for 30 minutes firstly, then the temperature was reduced to 25° C., 1 mmol Cd(DDTC)₂, 3 mmol Cd(AC)₂·2H₂O, 4 mmol Zn(AC)₂·2H₂O and 4 mmol Se/TOP were added, and the temperature was raised to 60° C. and continue for 30 minutes to remove water and oxygen to obtain a single molecule source precursor compound, and a molar ratio of Cd:Zn:Se:S in the single molecule source precursor compound is 1:1:1:1;
the single molecule source precursor compound was continuously removed water and oxygen at 25° C. for 30 minutes, then the temperature was raised to 150° C. and react for 60 minutes, and then raised the temperature to 250° C. and reacted for 80 minutes to obtain sulfur-containing quantum dot core of CdZnSeS.

### Example 6

This example is basically the same as Example 1 except that potassium ethylxanthate is used in this example instead of sodium diethyldithiocarbamate in Example 1 to obtain Cd (ex) 2.

### Example 7

This Example is basically the same as Example 1 except that 80° C. is used instead of 150° C. in Example 1.

### Example 8

This Example is basically the same as Example 1 except that 200° C. is used instead of 150° C. in Example 1.

### Example 9

This Example is basically the same as Example 5 except that 80° C. is used instead of 150° C. in Example 5.

### Example 10

This Example is basically the same as Example 5 except that 200° C. is used instead of 150° C. in Example 5.

### Comparative Example 1

0.1 mmol of cadmium oxide, 0.2 mmol of zinc acetate, 1 mL of oleic acid and 10 mL of octadecene were mixed under vacuum at 120° C. for 30 min;
the temperature was raised to 280° C. under argon atmosphere, then a mixed solution of 0.1 mmol Se/TOP and 0.2 mmol S/TOP was injected, and then matured for 20 minutes to obtain a sulfur-containing quantum dot core of ZnCdSeS;
CdZnS/ZnS shells were epitaxial growth on the sulfur-containing quantum dot core of ZnCdSeS.

### Comparative Example 2

0.4 mmol of cadmium oxide, 0.4 mmol of zinc acetate, 1 mL of oleic acid and 10 mL of octadecene were mixed under vacuum at 120° C. for 30 min;
the temperature was raised to 280° C. under argon atmosphere, then an n-octylphosphine solution mixed with 0.4 mmol Se and 0.4 mmol S was injected, and then matured for 20 minutes to obtain a sulfur-containing quantum dot core of ZnCdSeS;
CdZnS/ZnS shells were epitaxial growth on the sulfur-containing quantum dot core of ZnCdSeS.

### Comparative Example 3

0.2 mmol of cadmium oxide, 0.4 mmol of zinc acetate, 1 mL of oleic acid and 10 mL of octadecene were mixed under vacuum at 120° C. for 30 min;
the temperature was raised to 280° C. under argon atmosphere, then an n-octylphosphine solution mixed with 0.4 mmol S was injected, and then matured for 20 minutes to obtain a sulfur-containing quantum dot core of ZnCdS;
CdZnS/ZnS shells were epitaxial growth on the sulfur-containing quantum dot core of ZnCdS.

### Application Example 1

An ITO anode substrate were provided, and a thickness of the ITO anode is 100 nm;
PEDOT: PSS was spin-coated on the ITO anode substrate to form a hole injection layer having a thickness of 25 nm;
TFB was spin-coated on the hole injection layer to form a hole transport layer having a thickness of 20 nm;
the quantum dots of Example 1 were spin-coated on the hole transport layer to form a light-emitting layer having a thickness of 30 nm;
zinc oxide was spin-coated on the light-emitting layer to form an electron transport layer having a thickness of 40 nm;
Ag was vapor-deposited on the electron transport layer to form a cathode having a thickness of 80 nm;
packaged to obtain a light-emitting device, that is a quantum dot light-emitting diode.

### Application Examples 2 to 10

Application Examples 2 to 10 are basically the same as Application Example 1 except that the quantum dots of Example 1 are replaced with the quantum dots of Examples 2 to 10, respectively.

### Application Comparative Examples 1 to 3

Application Comparative Examples 1 to 3 are basically the same as Application Example 1 except that the quantum dots of Example 1 are replaced with the quantum dots of Examples 1 to 3, respectively.

Quantum dot light-emitting device test

The light-emitting diodes of Application Examples 1 to 10 and Application Comparative Examples 1 to 3 were tested for full width at half maximum (FWHM), fluorescence emission wavelength (PL), fluorescence quantum yield (PLQY), external quantum efficiency (EQE), and lifetime (T95@1000 nit).

The full width at half maximum (FWHM) of the light-emitting diodes were calculated by testing a Keithley 2400 high-precision digital source meter, an Ocean Optic USB2000+ spectrometer, and an LS-160 luminance meter.

The fluorescence emission wavelength (PL) is calculated by testing the F-7000 fluorescence spectrophotometer.

Fluorescence quantum yield (PLQY) was tested using a steady-state fluorescence spectrometer of Edinburgh Instruments Company. The model of the instrument is FS5, and the accessory corresponding to measuring fluorescence quantum yield is SC-30.

The test method of external quantum efficiency (EQE) is as follows:

The EQE is the ratio of electron-hole logarithm injected into quantum dot to the number of photons emitted, and the unit of the EQE is %. The EQE is an important parameter to measure the advantages and disadvantages of electroluminescent devices, which can be obtained by measuring it by EQE optical testing instrument. The specific calculation formula is as follows:

$$EQE = η e η r χ \frac{{K}_{R}}{{K}_{R} + {K}_{NR}} ;$$

Where, ηe is the optical output coupling efficiency, ηr is the ratio of the number of recombined carriers to the number of injected carriers, χ is the ratio of the number of excitons generated by photons to the total number of excitons, K_{R} is the radiation process rate, and K_{NR} is the non-radiation process rate.

Test conditions: at room temperature, and the air humidity is 30-60%.

The test method of life T95@1000 nit is as follows:

A time required for the light-emitting device to reduce its brightness to a certain proportion of the highest brightness under a constant current or a constant voltage drive is tested. The time when the brightness drops to 95% of the highest brightness is defined as T95, and this lifetime is the measured lifetime. In order to shorten the test cycle, the device lifetime test is usually carried out with reference to the device test under high brightness through the aging of the accelerator device, and the lifetime under high brightness is fitted by the extended exponential decay brightness attenuation fitting formula, for example: the lifetime at 1000 nit is T950000 nit. A specific calculation formula is as follows:

$$T {95}_{L} = T {95}_{H} \cdot {( \frac{{L}_{H}}{{L}_{L}} )}^{A} ;$$

In the formula, T95_{L} is a lifetime at low brightness, T95_{H} is a measured lifetime at high brightness, L_{H} is the highest brightness of the device, L_{L} is 1000 nit, and A is an acceleration factor.

TABLE 1

| | PL | FWHM | PLQY | EQE | LT95@1000 nit |
|---|---|---|---|---|---|
| items | (nm) | (nm) | (%) | (%) | (h) |
| Application | 480 | 18 | 80 | 17 | 100 |
| Example 1 | | | | | |
| Application | 470 | 16 | 82 | 19 | 80 |
| Example 2 | | | | | |
| Application | 472 | 17 | 80 | 19 | 120 |
| Example 3 | | | | | |
| Application | 545 | 25 | 85 | 18 | 4500 |
| Example 4 | | | | | |
| Application | 540 | 23 | 86 | 18.5 | 4300 |
| Example 5 | | | | | |
| Application | 538 | 24 | 82 | 18.7 | 4000 |
| Example 6 | | | | | |
| Application | 625 | 21 | 84 | 18 | 90 |
| Example 7 | | | | | |
| Application | 630 | 22 | 88 | 19 | 130 |
| Example 8 | | | | | |
| Application | 625 | 21 | 84 | 18 | 2800 |
| Example 9 | | | | | |
| Application | 628 | 22 | 85 | 19.2 | 3100 |
| Example 10 | | | | | |
| Application | 541 | 28 | 65 | 12 | 1800 |
| Comparative | | | | | |
| Example 1 | | | | | |
| Application | 630 | 27 | 68 | 10 | 1200 |
| Comparative | | | | | |
| Example 2 | | | | | |
| Application | 473 | 15 | 63 | 11 | 30 |
| Comparative | | | | | |
| Example 3 | | | | | |

As can be seen from Table 1:

As can be seen from Application Examples 1 to 3 and Application Comparative Example 3, the fluorescence emission wavelengths of the sulfur-containing quantum dot cores of Application Examples 1 to 3 and Application Comparative Example 3 are in the wavelength range of blue light. In the wavelength range of blue light, the fluorescence quantum yield, the external quantum efficiency, and the lifetime of the light-emitting devices of Application Examples 1 to 3 were all higher than those of Application Comparative Example 3. This is because by using the single-molecule source precursor in Application Examples 1 to 3, the defects of the sulfur-containing quantum dot core are reduced, and the defects of the generated core-shell quantum dots are reduced, and finally the fluorescence quantum yield, external quantum efficiency, and lifetime of the light-emitting device are improved.

As can be seen from Application Examples 4 to 10 and Application Comparative Examples 1 to 2, the fluorescence emission wavelengths of the sulfur-containing quantum dot cores of Application Examples 1 to 3 and Application Comparative Example 3 are in the wavelength range of red light. In the wavelength range of red light, the fluorescence quantum yield, the external quantum efficiency, and the lifetime of the light-emitting devices of Application Examples 4 to 10 were all higher than those of Application Comparative Examples 1 to 2. This is because by using the single-molecule source precursor in Application Examples 4 to 10, the defects of the sulfur-containing quantum dot core are reduced, and the defects of the generated core-shell quantum dots are reduced, and finally the fluorescence quantum yield, external quantum efficiency, and lifetime of the light-emitting device are improved.

As can be seen from Application Examples 7 to 8 and Application Comparative Example 3, in Application Examples 7 to 8, by slowly releasing anions and cations at 80-200° C. in the process of heating with a single molecule source, lattice defects and regular morphology can be ensured, and at the same time, the defects of the sulfur-containing quantum dot core are reduced, thereby reducing the defects of the generated core-shell quantum dots, and finally improving the fluorescence quantum yield, external quantum efficiency and lifetime of the light-emitting device. In Application Example Comparative Example 3, the anions and cations are released too quickly, which leads to an increase in defects in sulfur-containing quantum dot core, and ultimately shortens the lifetime of the light-emitting device.

As can be seen from Application Examples 9 to 10 and Application Comparative Examples 1 to 2, in Application Examples 9 to 10, by slowly releasing anions and cations at 80-200° C. in the process of heating with a single molecule source, lattice defects and regular morphology can be ensured, and at the same time, the defects of the sulfur-containing quantum dot core are reduced, thereby reducing the defects of the generated core-shell quantum dots, and finally improving the fluorescence quantum yield, external quantum efficiency and lifetime of the light-emitting device. In Application Example Comparative Examples 1 to 2, the anions and cations are released too quickly, which leads to an increase in defects in sulfur-containing quantum dot core, and ultimately shortens the lifetime of the light-emitting device.

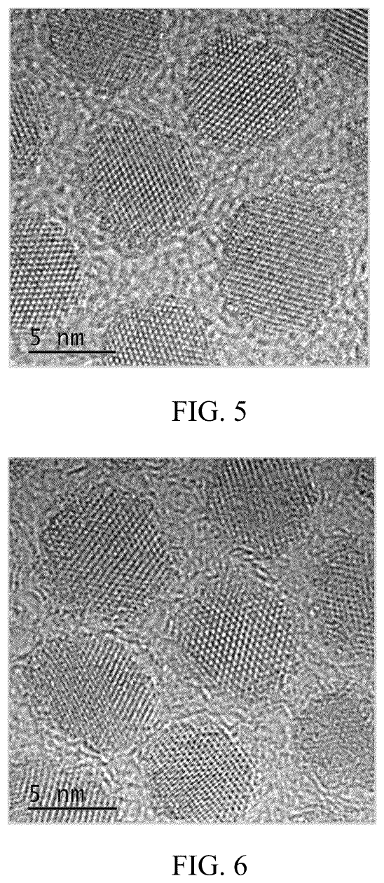

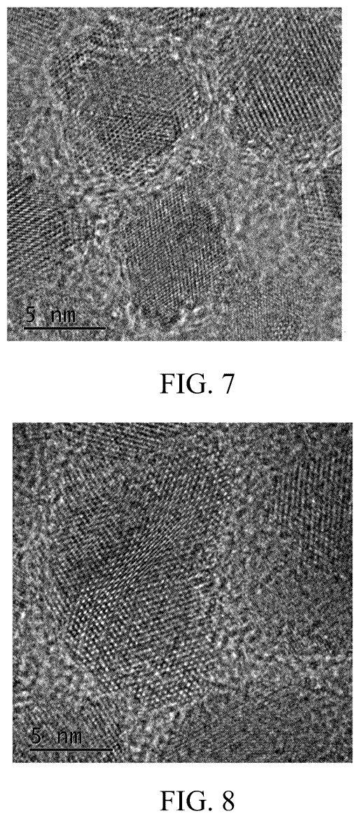

Referring to FIG. 5 to FIG. 8, FIG. 5 is a transmission electron microscope (TEM) image of the sulfur-containing quantum dot cores of Example 2 according to an embodiment of the present disclosure, FIG. 6 is a TEM image of the sulfur-containing quantum dot cores of Example 5 according to an embodiment of the present disclosure, FIG. 7 is a TEM image of the sulfur-containing quantum dot cores of Comparative Example 1, and FIG. 8 is a TEM image of the sulfur-containing quantum dot cores of Comparative Example 2. As can be seen from the images, the morphology of the sulfur-containing quantum dots prepared in Example 2 and Example 5 is more regular, while the morphology of Comparative Example 1 and Comparative Example 2 is irregular. Compared with Comparative Examples 1 to 2, the internal structure of the sulfur-containing quantum dot crystal prepared by the single molecule source precursor solution is more stable, and at the same time, the obtained sulfur-containing quantum dot nuclei have fewer defects.

The quantum dot material and preparation method thereof, and the light-emitting diode according to embodiments of the present disclosure are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. A method of preparing a quantum dot, comprising:
providing a single molecule source precursor solution, the single molecule source precursor solution comprises a single molecule source precursor compound comprising a first metal ion and a first anion;
heating the single molecule source precursor solution to obtain a sulfur-containing quantum core; and
forming one or more shell layers on the surface of the sulfur-containing quantum dot core to obtain the quantum dot;
wherein the first anion is selected from one or more of Formula (I), Formula (II), and Formula (III), and the structures of Formula (I), Formula (II), and Formula (III) are as follows: 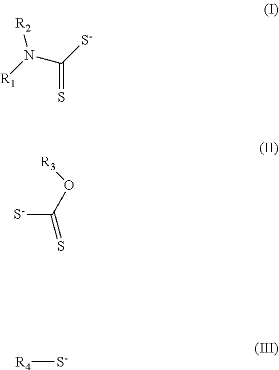
where R₁, R₂, R₃, and R₄ are independently selected from one of a substituted or unsubstituted C₁-C₂₄ alkyl group, a substituted or unsubstituted C₃-C₁₀ cycloalkyl group, a substituted or unsubstituted aryl group having 6 to 24 ring atoms, and a substituted or unsubstituted heteroaryl group having 5 to 24 ring atoms; and
the substituted substituent is selected from deuterium, amino, halogen, hydroxyl, carboxyl, nitro, aldehyde, cyano, C₁-C₆ alkyl, C₁-C₆ alkoxy, C₁-C₆ alkoxycarbonyl, and C₁-C₆ alkylacyloxy.

2. The method according to claim 1, wherein R₁, R₂, R₃, and R₄ are independently selected from C₁-C₁₆ alkyl group.

3. The method according to claim 1, wherein the first metal ion is selected from one or more of zinc ion, cadmium ion, indium ion, lead ion, and mercury ion.

4. The method according to claim 1, wherein the first anion comprises one or more of dithiocarbamate acid radical, xanthate acid radical, and thiol anion.

5. The method according to claim 4, wherein the dithiocarbamate acid radical comprises one or more of dimethyldithiocarbamate acid radical, diethyldithiocarbamate acid radical, dipropyldithiocarbamate acid radical, and dibutyldithiocarbamate acid radical;
the xanthate acid radical comprises one or more of methyl xanthate acid radical, ethyl xanthate acid radical, propyl xanthate acid radical, butyl xanthate acid radical, tetradecyl xanthate acid radical, pentadecyl xanthate acid radical, and hexadecyl xanthate acid radical; and
the thiol anion is selected from one or more of methanethiol anion, ethanethiol anion, propanethiol anion, and dodecanethiol anion.

6. The method according to claim 1, wherein the single molecule source precursor solution further comprises a second metal ion and/or a second anion source.

7. The method according to claim 6, wherein the second metal ion is selected from one or more of zinc ion, cadmium ion, indium ion, lead ion, and mercury ion.

8. The method according to claim 6, wherein the second anion source comprises one or more of selenium source, phosphorus source, and antimony source; wherein the selenium source comprises one or more of elemental selenium, sodium selenide, and potassium selenide; the phosphorus source comprises one or more of elemental phosphorus, trialkylphosphine, tris (trialkylsilyl) phosphine, tris (dialkylsilyl) phosphine, and tris (dialkylamino) phosphine; and the antimony source comprises one or more of elemental antimony, antimony tribromide, and antimony chloride.

9. The method according to claim 1, wherein a solvent of the single molecule source precursor solution comprises a coordinating solvent and/or a non-coordinating solvent.

10. The method according to claim 9, wherein the coordinating solvent comprises an aliphatic amine compound having 4 to 30 carbon atoms and/or an acid compound having 4 to 24 carbon atoms, the aliphatic amine compound comprises an alkylamine and/or an alkenylamine, the acid compound comprises a fatty acid compound, and the fatty acid compound comprises an alkenoic acid.

11. The method according to claim 10, wherein the coordinating solvent comprises one or more of octylamine, dioctylamine, trioctylamine, oleylamine, oleic acid, linoleic acid, stearic acid, palmitic acid, dodecenoic acid, tridecenoic acid, tetradecenoic acid, pentadecenoic acid, hexadecenoic acid, and heptadecenoic acid.

12. The method according to claim 10, wherein the non-coordinating solvent comprises a hydrocarbon compound, and the hydrocarbon compound comprises an alkene having 6 to 24 carbon atoms and/or an alkane having 6 to 24 carbon atoms.

13. The method according to claim 10, wherein the non-coordinating solvent comprises one or more of dodecene, tetradecene, hexadecene, heptadecene, octadecene, and paraffin.

14. The method according to claim 1, wherein the heating comprises:
heating at a first temperature for a first preset time to obtain a sulfur-containing quantum dot;
wherein the first temperature is 200-280° C., and the first preset time is 20-120 min.

15. The method according to claim 1, wherein before the heating, the method further comprises preheating, and the preheating comprises:
heating at a second temperature for a second preset time;
wherein the second temperature is 80-200° C., and the second preset time is 20-120 min.

16. The method according to claim 15, wherein before the preheating, the method further comprises pretreatment, and the pretreatment comprises:
heating at a third temperature for a third preset time;
wherein, the third temperature is 25-60° C., and the third preset time is 20-120 min.

17. A quantum dot, wherein the quantum dot is prepared by the method according to claim 1.

18. The quantum dot according to claim 17, wherein a material of the sulfur-containing quantum dot core is selected from one or more of ZnS, CdS, InS, PbS, HgS, ZnCdS, ZnInS, ZnPbS, ZnHgS, CdInS, CdPbS, CdHgS, InPbS, InHgS, PbHgS, ZnSeS, CdSeS, InSeS, PbSeS, HgSeS, ZnPS, CdPS, InPS, PbPS, HgPS, ZnSbS, CdSbS, InSbS, PbSbS, HgSbS, ZnCdSeS, ZnInSeS, ZnPbSeS, ZnHgSeS, CdInSeS, CdPbSeS, CdHgSeS, InPbSeS, InHgSeS, PbHgSeS, ZnCdPS, ZnInPS, ZnPbPS, ZnHgPS, CdInPS, CdPbPS, CdHgPS, InPbPS, InHgPS, PbHgPS, ZnCdSbS, ZnInSbS, ZnPbSbS, ZnHgSbS, CdInSbS, CdPbSbS, CdHgSbS, InPbSbS, InHgSbS, PbHgSbS; and
materials of each of the shell layers are independently selected from one or more of CdS, CdSe, CdTe, ZnS, ZnSe, ZnTe, ZnO, HgS, HgSe, HgTe, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, CdZnSeS, CdZnSeTe, CdZnSTe, CdHgSeS, CdHgSeTe, CdHgSTe, HgZnSeS, HgZnSeTe, HgZnSTe, SnS, SnSe, SnTe, PbS, PbSe, PbTe, SnSeS, SnSeTe, SnSTe, PbSeS, PbSeTe, PbSTe, SnPbS, SnPbSe, SnPbTe, SnPbSSe, SnPbSeTe, SnPbSTe, GaN, GaP, GaAs, GaSb, AlN, AlP, AlAs, AlSb, InN, InP, InAs, InSb, GaNP, GaNAs, GaNSb, GaPAs, GaPSb, AlNP, AlNAs, AlNSb, AlPAs, AlPSb, InNP, InNAs, InNSb, InPAs, InPSb, GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, CuInS₂, CuInSe₂, and AgInS₂.

19. A light-emitting device, comprising:
an anode, a light-emitting layer, and a cathode which are stacked;
wherein the light-emitting layer comprises the quantum dot according to claim 17.

20. The light-emitting device according to claim 19, wherein materials of the anode and the cathode are each independently selected from one or more of indium-doped tin oxide, fluorine-doped tin oxide, antimony-doped tin oxide, aluminum-doped zinc oxide, gallium-doped zinc oxide, indium-doped zinc oxide, magnesium-doped zinc oxide, aluminum-doped magnesium oxide, AZO/Ag/AZO, AZO/Al/AZO, ITO/Ag/ITO, ITO/Ag/ITO, ZnO/Ag/ZnO, ZnS/Ag/ZnS, Ag, Al, Cu, Mo, Au, Pt, Si, Ca, Mg, and Ba;
the light-emitting device further comprises a hole functional layer comprising one or more of a hole transport layer and a hole injection layer, wherein the hole injection layer is disposed between the light-emitting layer and the anode, and the hole transport layer is disposed between the light-emitting layer and the hole injection layer; a material of the hole transport layer comprises one or more of 4,4′-N,N′-dicarbcarbazolyl-biphenyl, poly [bis(4-phenyl) (2,4,6-trimethylphenyl) amine], N,N′-diphenyl-N,N′-bis (1-naphthyl)-1,1′-biphenyl-4,4″-diamine, N,N′-diphenyl-N,N′-bis (1-naphthyl)-4,4′-diamine, poly (N,N′bis(4-butylphenyl)-N,N′-bis (phenyl) benzidine), N,N′-bis(3-methylphenyl)-N,N′-bis (phenyl)-spiro, N,N′-bis(4-(N,N′-diphenyl-amino) phenyl)-N,N′-diphenyl benzidine, 4,4′,4′-tris (N-carbazolyl)-triphenylamine, 4,4′,4′-tris (N-3-methylphenyl-N-phenylamino) triphenylamine, poly [(9,9′-dioctyl fluorene-2,7-diyl)-co-(4,4′-(N-(4-sec-butylphenyl) diphenylamine))], poly (N-vinylcarbazole) and its derivatives, N,N′-bis(1-naphthyl)-N,N′-diphenyl-1,1′-biphenyl-4-4′-diamine, spiro NPB, poly (phenylene vinylene), poly [2-methoxy-5-(2-ethylhexyloxy)-1,4-phenylene vinylene], poly [2-methoxy-5-(3′,7′-dimethyloctyloxy)-1,4-phenylene vinylene], 2,2′,7,7′-tetrakis [N,N-bis(4-methoxyphenyl) amino]-9,9′-spiro-fluorene, 4,4′-cyclohexyl bis [N,N-bis(4-methylphenyl) aniline], 1,3-bis (carbazole-9-yl) benzene, polyaniline, polypyrrole, poly (p) phenylene vinylene, aromatic tertiary amine, polynuclear aromatic tertiary amine, 4,4′-bis (p-carbazolyl)-1,1′-biphenyl compound, N,N,N′,N′-tetraarylbenzidine, poly (3,4-ethylenedioxythiophene)-polystyrene sulfonic acid and its derivatives, polymethacrylate and its derivatives, poly (9,9-octylfluorene) and its derivatives, polyspirofluorene and its derivatives, doped graphene, undoped graphene, C60, doped or undoped NiO, doped or undoped MoO₃, doped or undoped WO₃, doped or undoped V₂O₅, doped or undoped P-type gallium nitride, doped or undoped CrO₃, and doped or undoped CuO; a material of the hole injection layer comprises one or more of 2,3,6,7,10,11-hexacyano-1,4,5,8,9,12-hexazaphenanthrene, polyoxyethyl cephene, PEDOT:PSS, PEDOT:PSS doped with MoO₃, 4,4′,4′-tris (N-3-methylphenyl-N-phenylamino) triphenylamine, tetracyanoquinone dimethane, copper phthalocyanine, nickel oxide, molybdenum oxide, tungsten oxide, vanadium oxide, molybdenum sulfide, tungsten sulfide and copper oxide;
the light-emitting device further comprises an electron functional layer disposed between the light-emitting layer and the cathode, the electron functional layer comprises one or more of an electron injection layer and an electron transport layer; a material of the electron transport layer is selected from one or more of an inorganic electron transport material and an organic electron transport material; the inorganic electron transport material comprises one or more of a doped metal oxide particle, an undoped metal oxide particle, a ceramic semiconductor material, a Group IIB-VIA semiconductor material, a Group IIIA-VA semiconductor material, and a Group IB-IIIA-VIA semiconductor material; the metal oxide in the undoped metal oxide particle comprises one or more of ZnO, TiO₂, SnO₂, ZrO₂, Ta₂O₅; the metal oxide in the doped metal oxide comprises one or more of ZnO, TiO₂, SnO₂, ZrO₂, Ta₂O₅, and Al₂O₃, and the doping element in the doped metal oxide comprises one or more of Al, Mg, Li, Mn, Y, La, Cu, Ni, Zr, Ce, In, Ga, and Sn; the ceramic semiconductor material comprises barium titanate; the Group IIB-VIA semiconductor material comprises one or more of ZnS, ZnSe, and CdS; the Group IIIA-VA semiconductor material comprises one or more of InP and GaP; the Group IB-IIIA-VIA semiconductor material comprises one or more of CuInS and CuGaS; the organic electron transport material comprises one or more of a quinoxaline compound, an imidazole compound, a triazine compound, a fluorene-containing compound, and a hydroxyquinoline compound.
